(19) United States
(12) Patent Application Publication
(10) Pub. No.: US 2009/0028420 A1
(43) Pub. Date: Jan. 29, 2009

(54) PHOTOMASK DEFECT-SHAPE RECOGNITION APPARATUS, PHOTOMASK DEFECT-SHAPE RECOGNITION METHOD, AND PHOTOMASK DEFECT CORRECTION METHOD

(76) Inventors: Takuya Nakaue, Chiba-shi (JP); Atsushi Uemoto, Chiba-shi (JP); Osamu Takaoka, Chiba-shi (JP)

Correspondence Address: BRINKS HOFER GILSON & LIONE, P.O. BOX 10395, CHICAGO, IL, 60610, US

(21) Appl. No.: 12/175,061

(22) Filed: Jul. 17, 2008

(30) Foreign Application Priority Data
Jul. 24, 2007 (JP) JP2007-191766

(51) Int. Cl. G06K 9/00; G03F 1/00

(52) U.S. Cl. 382/144; 430/5

(57) ABSTRACT

To recognize a defect portion and a mask pattern with a distinctly distinguished state through AFM observation of a photomask without being influenced by a double-tips image, provided is a method of recognizing, through AFM observation of a photomask including a substrate (2) and the mask pattern formed on the substrate (2a) with a predetermined pattern, a shape (5) of a projection type defect portion projected from the mask pattern, including the steps of storing a reference image an observation image in which an edge line of the defect portion is first confirmed at the time of AFM observation; and correcting, after the storing step, the edge line (L2) of the defect portion confirmed through the observation image obtained by the scanning performed hereinafter into a normal line (L1) with reference to the reference image, in which the shape of the defect portion is recognized based on the observed image after the correction.

### RELATED APPLICATIONS

This application claims priority under 35 U.S.C. §119 to Japanese Patent Application No. JP2007-191766 filed on Jul. 24, 2007, the entire content of which is hereby incorporated by reference.

1. Technical Field

The present invention relates to a photomask defect-shape recognition apparatus and a photomask defect-shape recognition method of subjecting a defect portion of the photomask, which is used when manufacturing a semiconductor, to cutting processing to correct the defect, and a photomask defect correction method of removing the recognized defect portion to correct the photomask.

2. Description of the Related Art

The photomask, which is used when manufacturing a semiconductor, becomes an original plate for a pattern, and hence after drawing a mask pattern on a mask substrate, an inspection of presence or absence of the defect portion is always conducted, and the correction of the defect portion is optionally carried out.

The photomask is drawn on the mask substrate with a drawing apparatus based on drawing data designed in advance. With this, the photomask having a mask pattern drawn on the mask substrate is prepared. Further, after preparing the photomask, the presence or absence of the defect and location of the defect portion are inspected using a defect inspection apparatus, and if any defect is present, defect correction processing with a photomask correction apparatus is carried out before the photomask is transferred onto a wafer.

As the kinds of the defect of the mask pattern, for example, a projection which excessively projects from a desired pattern and becomes the projection (protrusion), a recess such as a cutaway is caused in the desired pattern (intrusion), and the like are given. Those defect portions are corrected as follows. After the location of the defect portion is identified by the defect inspection apparatus, the shape of the defect portion is recognized in detail by the photomask defect correction apparatus and also cutting processing is conducted with respect to the defect which becomes a projection, and about pattern lacking, a light-blocking film is formed on the recess portion to be corrected.

As methods of removing processing at this time, there are known various methods. However, as one of those, there is known a method involving using an atomic force microscope (AFM) to correct the defect portion (see, “Defect repair performance using the nanomachining repair technique,” 2003, Proc. of SPIE 5130, P520-P527, written by Y Morikawa, H. Kokubo, M. Nishiguchi, N. Hayashi, R. White, R. Bozak, and L. Terrill).

This method involves observing a predetermined area on the mask substrate with a probe having a probe tip at a tip thereof using AFM to specify in detail the defect portion of the mask pattern, and then the defect portion is subjected to the cutting processing using the same probe. In particular, this method is effective in a case where the defect portion excessively protrudes from a desired pattern to form a projection-like shape.

Detailed description is made of this method with reference to FIG. 14. Note that, FIG. 14 illustrates a mask pattern 31 drawn on a substrate 30, and is viewed from upward thereof, in which a projection type defect portion 32 locates on the mask pattern 31.

At first, existence of the defect portion 32 on the mask pattern 31 is confirmed in advance with a defect inspection apparatus, and a position of the defect portion 32 is specified. Then, before conducting the correction with the photomask defect correction apparatus, periphery of the defect portion 32 is set as an observation area E based on the positional data.

If the observation area E is specified, the photomask defect correction apparatus scans the probe within the observation area E. Specifically, the scanning is performed while a distance between the probe tip and the mask substrate 30 is height-controlled so that the bending of the probe becomes constant. In this case, the scanning is performed in a direction parallel to the mask pattern 31 (arrow A1 direction), and the scanning is performed repeatedly multiple times from a tip side of the defect portion 32 towards a root side (mask pattern 31 side) (towards arrow A2 direction). With this operation, surface observation of the mask substrate 30 within the observation area E may be made, and images of a part of the mask pattern 31 and the defect portion 32 may be obtained to extract an edge line of a straight line pattern without defect from the images through image processing. The edge line of the defect portion 32 is assumed from the extracted edge line, and an excessive portion outside the assumed edge line may be recognized as the defect.

Subsequently, after the recognition of the defect portion 32 by the above-mentioned method, the scanning is performed while pressing the probe to the defect portion 32 with a predetermined force. With this operation, by using a harder probe tip than a material to be processed (projection type defect), it is possible to cut the recognized defect portion 32 with mechanical processing. Then, by repeatedly performing the scanning at multiple times, the entire defect portion 32 may be subjected to the cutting processing to remove the defect portion 32.

Specifically, the probe is scanned in a direction parallel to the mask pattern 31 (arrow A1 direction) to cut the defect portion 32 in a line shape, and the scanning is repeatedly performed at multiple times from the tip of the defect portion 32 towards the root side of the defect portion 32 (towards arrow A2 direction), the entire defect portion 32 may be subjected to the cutting processing.

The reason why the cutting is performed in the above-mentioned direction (arrow A2 direction) is to reduce cutting resistance as much as possible. If the cutting processing is performed from the root side towards the tip side (opposite direction to arrow A2 direction), there is a fear of being not able to cut well due to large cutting resistance. In particular, as described above, the photomask becomes an original plate of the pattern, and when subjecting the defect portion 32 to the cutting processing, processing with high precision is required. For that reason, the cutting processing is performed in the above-mentioned direction. As those results, the projection type defect portion 32 may be removed to correct the mask pattern 31 into a correct one.

However, in the above-mentioned conventional method, the following problems are remained unsolved.

At first, for the probe tip provided to the tip of the probe, a hard material (diamond, etc.) is employed for cutting processing the defect portion 32. Therefore, at the time of AFM observation, as illustrated in FIG. 15, there was a case where a part of the defect portion 32 is scooped by the probe tip 33. In particular, the scoop is liable to cause at a portion where the probe tip 33 runs up the defect portion 32. Moreover, the scooped portion attaches to the probe tip 33 as it is, and becomes a mere foreign matter X, hereinafter.

Like this, during the observation, if the foreign matter X once attaches to the vicinity of the probe tip, the observation must be performed with the probe tip 33 as it stands to which the foreign matter X attaches. Accordingly, from both the tip of the probe tip and the foreign matter X interatomic forces are detected and form double image which is convoluted with both the interatomic forces (hereinafter, referred to as double-tips image), thereby being not possible to obtain an accurate image. Moreover, there is such a risk that the defect portion 32 is scooped again due to the foreign matter X attached before, and as illustrated in FIG. 1, there is a fear of being newly attached with another foreign matter X.

As described above, there was a case of being not possible to obtain a normal image due to the influence of the foreign matter attached to the probe tip 33. In particular, there is not much influenced for the first observation, but in the case of performing the processing after the observation of multiple times, it is likely to cause a double-tips image.

In this case, the direction for repeating the scanning at the time of the observation is from the tip side of the defect portion 32 towards the root side being the mask pattern 31 side (towards arrow A2 direction), and therefore, as illustrated in FIG. 17 and FIG. 18, the image in the periphery of the root of the defect portion 32 becomes a double-tips image. For that reason, the contour in the vicinity of the root side of the defect portion 32 or the edge shape of the mask pattern 31 may not sometime be recognized accurately. Specifically, the edge portion is blurred to be unclear or double, thereby being not able to obtain a clear image.

In particular, it is not possible to correctly recognize the edge shape of the mask pattern 31, thereby being difficult to distinguish the mask pattern 31 from the defect portion 32. For that reason, not only the defect portion 32 may not be removed with high accuracy by the cutting processing, but also have a fear of cutting the mask pattern 31. On the contrary, because the mask pattern 31 and the defect portion 32 may not be clearly distinguished therebetween, if the defect portion 32 is largely left uncut, additional processing is required, resulting in degradation of the working efficiency.

Therefore, to eliminate a double-tips image, it is conceivable to optionally conduct cleaning of the probe tip 33 to remove the foreign matter X attached to the probe tip 33. However, it takes a time for cleaning to cause the reduction of throughputs. Further, when conducting the cleaning, it involves a long distance stage movement, and hence in a usual high accuracy stage using a ball screw, a thermal drift occurs due to friction of the ball screw. For that reason, the processing position is displaced from a desired position so that it was difficult to conduct the cutting processing with high accuracy.

### SUMMARY OF THE INVENTION

The present invention has been made in view of the above-mentioned circumstances, and has a primary object to provide a photomask defect-shape recognition apparatus and a photomask defect-shape recognition method which are capable of performing AFM observation of a photomask without being influenced by a double-tips image to recognize the defect shape of the photomask while distinctly distinguished state between the defect portion and the mask pattern. In addition, it is another object of the invention to provide a photomask correction method involving removing with high accuracy an accurately recognized defect portion to correct the photomask.

In order to attain the above-mentioned object of the invention, the present invention provides the following means.

According to the present invention, there is provided a photomask defect-shape recognition apparatus for recognizing through AFM observation a shape of a projection type defect portion projected from a mask pattern of a photomask including a substrate and the mask pattern formed on the substrate with a predetermined pattern,

the photomask defect-shape recognition apparatus including:

a stage for fixing the photomask;

a probe having a probe tip provided on a tip of the probe, the probe tip being disposed opposingly to the substrate;

a moving means for relatively moving the substrate and the probe in a parallel direction of a surface of the substrate and in a vertical direction of the surface of the substrate;

a displacement measuring means for measuring displacement of the probe; and

a control means for repeatedly scanning multiple times, based on a result of measurement by the displacement measuring means, while controlling a distance between the probe tip and a surface of the substrate so that the displacement of the probe becomes constant, to thereby subject the defect portion to AFM observation, in which

the control means comprises: a storing section for storing as a reference image an observation image in which an edge line of the defect portion is first confirmed at a time of AFM observation; and a correction section for correcting the edge line of the defect portion confirmed through the observation image obtained by the scanning performed hereinafter into a normal line with reference to the reference image, and recognizes the shape of the defect portion based on the observed image after the correction.

Further, according to the present invention, there is provided a photomask defect-shape recognition method for recognizing through AFM observation a shape of a projection type defect portion projected from a mask pattern of a photomask including a substrate and the mask pattern formed on the substrate with a predetermined pattern by repeatedly scanning multiple times using a probe having a probe tip provided on a tip of the probe, while controlling a distance between the probe tip and a surface of the substrate so that a displacement of the probe becomes constant,

the photomask defect-shape recognition method including the steps of:

storing as a reference image an observation image in which an edge line of the defect portion is first confirmed at the time of AFM observation; and

correcting, after the storing step, the edge line of the defect portion confirmed through the observation image obtained by the scanning performed hereinafter into a normal line with reference to the reference image, in which

the shape of the defect portion is recognized based on the observed image after the correction.

According to the photomask defect-shape recognition apparatus and the photomask defect-shape recognition method, first, the photomask having a mask pattern including a given pattern drawn on the substrate in advance is fixed on the stage. After fixing the photomask, the periphery of the projection type defect portion whose location is specified by another means is specified as the observation area.

If the observation area is specified, the control means scans the probe within the observation area to obtain the observation image through AFM observation, and performs a step of recognizing the shape of the defect portion in detail. Specifically, the scanning is performed repeatedly multiple times while controlling a distance between the probe tip and the substrate surface so that the displacement of the probe becomes constant to obtain the observation image. With this operation, the observation of the surface of the substrate within the specified observation area may be performed, thereby being capable of recognizing a part of the mask pattern and the contour shape of the defect portion.

Specifically describing the AFM observation, first, the AFM observation is started, and then performs the storing step of storing as the reference image the observation image in which the contour line (edge line) of the defect portion is first confirmed to a storing section. Specifically, the observation image obtained using a clean probe tip to which no foreign matter is attached, is stored in advance as the reference image. Thereafter, the scanning is repeated for AFM observation. However, there is a fear of a part of the defect portion, which has been cut by the probe tip during the scanning, being attached thereto. In this case, the obtained observation image becomes a double-tips image, resulting in impossible to clearly recognize the edge line. However, the observation image, which has been obtained when the probe tip is still clean, is stored, thereby being capable of obtaining the accurate edge line of the defect portion without being influenced by the double-tips image.

Subsequently, the scanning is repeatedly performed to conduct AFM observation within the observation area. However, the observation image to be obtained by the scanning performed after the storing step may have a fear of causing the double-tips image. Therefore, the correction section performs the correction step of correcting the edge line of the defect portion confirmed by the observation image obtained by the scanning performed after the storing step into a normal line with reference to the reference image. By performing this correction, the influence caused by the double-tips due to the attachment of the foreign matter to the probe tip may be cancelled, and a correct edge line of the defect portion may be presumed.

As a result, it is possible to accurately recognize the contour shape of the defect portion while distinctly distinguishing the mask pattern from the defect portion with out being influenced by the double-tips image.

Further, according to a photomask defect-shape recognition apparatus of the present invention, in the photomask defect-shape recognition apparatus of the invention, the correction section compares the contour line stored in the storing section and the contour line obtained by the scanning performed after obtaining the reference image through matching to detect a difference therebetween, and corrects the line of a portion where the difference is detected, among the contour lines obtained by the scanning performed after obtaining the reference image, so as to match with the contour line stored in the storing section.

Further, according to a photomask defect-shape recognition method of the present invention, in the photomask defect-shape recognition method of the invention, in the correction step, the contour line stored in the storing section and the contour line obtained by the scanning performed after obtaining the reference image is compared through matching to detect a difference therebetween, and the line of a portion where the difference is detected, among the contour lines obtained by the scanning performed after obtaining the reference image, is corrected so as to match with the contour line stored in the storing section.

In the photomask defect-shape recognition apparatus and the photomask defect-shape recognition method of the present invention, when conducting the correction of the edge line, the edge line of the defect portion stored in the storing section and the edge line obtained by the scanning performed after obtaining the reference image are subjected to matching for comparison. In this case, in the case of being influenced by the double-tips image due to attachment of the foreign matter to the probe tip, both the edge lines do not completely match with each other, and the difference is caused only the portion which is influenced by the double-tips image. Therefore, the line of the portion where the difference is caused is corrected so as to match with the edge line stored in the storing section. With this operation, the correction of the portion, which is influenced by the double-tips, may be made, and hence the correct edge line of the defect portion may be assumed.

Further, according to a photomask defect-shape recognition apparatus of the present invention, in the photomask defect-shape recognition apparatus of the invention, the correction section determines an inclined angle of a side surface of the defect portion with respect to a substrate surface from the edge line of the observation image stored in a storing section to set the inclined angle as a reference angle, and determines thereafter an inclined angle of the side surface of the defect portion with respect to the substrate surface from the edge line obtained by the scanning performed after obtaining the reference image, to thereby correct the inclined angle so as to match with the reference angle.

Further, according to a photomask defect-shape recognition method of the present invention, in the photomask defect-shape recognition method of the invention, in the correction step, an inclined angle of a side surface of the defect portion with respect to a substrate surface is determined from the edge line of the observation image stored in a storing section to set the inclined angle as a reference angle, and thereafter an inclined angle of the side surface of the defect portion with respect to the substrate surface is determined from the edge line obtained by the scanning performed after obtaining the reference image, to thereby correct the inclined angle so as to match with the reference angle.

In the photomask defect-shape recognition apparatus and the photomask defect-shape recognition method of the present invention, when the correction of the edge line is performed, first, the inclined angle of the side surface of the defect portion with respect to the substrate surface is determined from the edge line of the defect portion stored in the storing section, and the determined angle is set as the reference angle. Typically, in the case where the foreign matter is attached to the probe tip, the observation image is influenced by the foreign matter to cause the double-tips image, and the side surface portion is most influenced. Specifically, in the observation image being the double-tips image, influences such as a blur of the image and a double-overlapped image cause to confirm the edge line of the defect portion in which the side surface portion is inflated or deformed. Accordingly, the inclined angle is determined in advance from the edge line which is not influenced by the double-tips image or the edge line stored in the storing section, and the determined inclined angle is set as the reference angle.

Then, from the edge line obtained by the scanning performed after obtaining the reference image, the inclined angle is determined as well. At this time, if the influence caused by the double-tips image due to attachment of the foreign matter to the probe tip is received, as described above, the edge line of the portion which corresponds to the side surface of the defect portion is influenced markedly, resulting in change in the inclined angle. Accordingly, by correcting the changed inclined angle so as to match with the reference angle, the portion, which is influenced by the double-tips image, may be corrected, and the accurate edge line of the defect potion may be presumed.

Further, according to a photomask defect-shape recognition apparatus of the present invention, in the photomask defect-shape recognition apparatus of the invention, the control means scans multiple times the recognized defect portion while pressing the probe tip with a predetermined force to cut the defect portion to be removed.

Further, according to the present invention, there is provided a photomask defect correction method, including, after recognition of a shape of a photomask defect portion by the photomask defect-shape recognition method of the invention, a processing step of repeatedly scanning multiple times while pressing a probe tip to the recognized defect portion with a predetermined force to cut and remove.

According to the photomask defect-shape recognition apparatus and the photomask defect correction method of the present invention, after conducting AFM observation, the scanning is performed repeatedly multiple times to the defect portion whose shape is recognized in detail through the AFM observation while pressing the probe tip thereto with a predetermined force, and the processing step of removing the defect portion through cutting is performed. In particular, different form the conventional apparatus and method, which is influenced by the double-tips image, through AFM observation, the defect portion and the mask pattern is distinctly distinguished and the contour shape of the defect portion is accurately recognized. Therefore, while preventing the troubles from occurring, such as cutting of the mask pattern by mistake and the remainder of the defect portion to be cut, the defect portion only may be removed by the cutting processing with high accuracy.

As a result, the correction of the mask pattern may be made with high accuracy. Further, the success of the correction enables to obtain the photo mask with high quality as an original plate for transfer of the image.

According to the photomask defect-shape recognition apparatus and the photomask defect-shape recognition method, AFM observation of the photomask may be carried out without being influenced by the double-tips image, and while distinctly distinguishing the defect portion from the mask pattern, it is possible to accurately recognize the contour shape of the defect portion.

In addition, according to the photomask defect-shape recognition apparatus and the photomask correction method, the recognized defect portion may be removed with high accuracy through the cutting processing.

### BRIEF DESCRIPTION OF THE DRAWINGS

In the accompanying drawings:

FIG. 1 is a perspective view of a photomask to which correction is performed by a photomask defect-shape recognition apparatus according to the present invention;

FIG. 2 is a block diagram illustrating a photomask defect-shape recognition apparatus according to an embodiment of the present invention;

FIG. 3 illustrates one process for correcting a defect portion produced on a mask pattern by the photomask defect-shape recognition apparatus of FIG. 2, in which movement of a probe when AFM observation is performed within a set observation area is viewed from upward of the mask pattern;

FIG. 4 is a diagram illustrating an observation image obtained as a result of the observation illustrated in FIG. 3, and is the observation image in which an edge line of the defect portion is first confirmed;

FIG. 5 is a diagram illustrating the observation image obtained as a result of the observation illustrated in FIG. 3, and is the observation image in which the edge line having received an influence is confirmed;

FIG. 6 illustrates a state in which correction is made to obtain a correct edge line by matching the edge line of the defect portion confirmed by the observation image illustrated in FIG. 4 with the edge line of the defect portion confirmed by the observation image illustrated in FIG. 5;

FIG. 7 illustrates a state in which the observation image of a case in which one entire side surface of the defect portion is influenced by the double-tips is subjected to matching with the observation image illustrated in FIG. 4;

FIG. 8 is an image view of a mask pattern and the defect portion, which is obtained as a result of the correction through the matching illustrated in FIG. 6;

FIG. 9 is a view viewed from an upward of the mask pattern and illustrates a movement of a probe tip at the time of cutting processing of the defect portion after completing the AFM observation;

FIG. 10 is a perspective view of the mask pattern after being subjected to the cutting processing;

FIGS. 11 are state views, in which FIG. 11A illustrates a state in which an edge line between the mask pattern and the defect portion is recognized in error as a result of performing AFM observation by a conventional method; FIG. 11B illustrates a result thereof; FIG. 11C illustrates a state in which a cutting remainder is caused at an actual defect portion as a result of subjecting the defect portion erroneously recognized to the cutting processing; FIG. 11D illustrates a state in which a region of the actual defect portion is accurately recognized with the photomask defect-shape recognition apparatus of the present invention; and FIG. 11E illustrates a state in which the cutting processing of the defect portion only may be carried out with high accuracy and without leaving the cutting remainder;

FIG. 12 illustrates a modification example of a case of correcting the edge line of the defect portion by the photomask defect-shape recognition apparatus of the present invention, in which an inclined angle of a side surface of the defect portion with respect to a substrate surface is determined from the edge line of the observation image stored in a storing section;

FIG. 13 illustrates a modification example of a case of correcting the edge line of the defect portion by the photomask defect-shape recognition apparatus of the present invention, in which the inclined angle of the side surface of the defect portion with respect to the substrate surface is determined;

FIG. 14 illustrates a conventional method of correcting the mask, in which, when conducting AMF observation, movement of a probe tip which is scanned in a direction parallel to a mask pattern and the scanning is repeatedly performed from a tip side of a defect portion towards the mask pattern side is viewed from the upward of the mask pattern;

FIG. 15 illustrates a state in which a foreign matter is attached to the probe tip when conducting the observation illustrated in FIG. 14;

FIG. 16 illustrates a state in which another foreign matter is further attached to the probe tip after the state illustrated in FIG. 15;

FIG. 17 is an image view of the mask pattern and the defect portion obtained by the probe tip illustrated in FIG. 15; and

FIG. 18 is a cross sectional view taken along an arrow A-A of FIG. 17.

### DETAILED DESCRIPTION OF THE PREFERRED EMBODIMENT

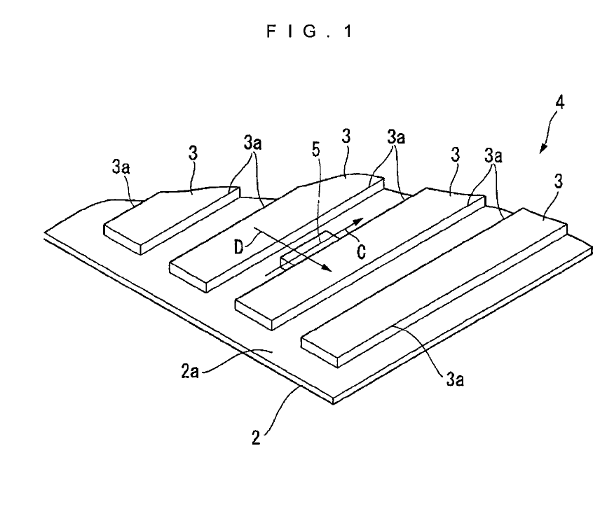

Hereinafter, descriptions are made of the photomask defect-shape recognition apparatus and the photomask defect-shape recognition method according to the present invention, and one embodiment of the photomask correction method with reference to FIGS. 1 to 11. Note that, in this embodiment, description is made of a case by way of an example in which an optical lever method is used.

The photomask defect-shape recognition apparatus 1 according to this embodiment is a apparatus, as illustrated in FIG. 1, for recognizing through AFM observation a shape of a projection type defect portion 5 projected from a mask pattern 3 of a photomask including a substrate 2 and the mask pattern 3 formed on the substrate with a predetermined pattern. Further, in this embodiment, not only performing the observation, but also performing removal of the defect portion 5 whose shape is recognized, through cutting processing for correction.

Note that, the photomask 4 is prepared by a drawing apparatus (not shown), and the mask pattern 3 is drawn on the substrate 2 based on drawing data designed in advance. Further, the photomask 4 is inspected with a defect inspection apparatus (not shown) after being prepared by the drawing apparatus, and hence a position of the defect portion 5 has already been specified. Further, the substrate 2 of the photomask 4 becomes a mask substrate, and is, for example, a glass or quartz substrate.

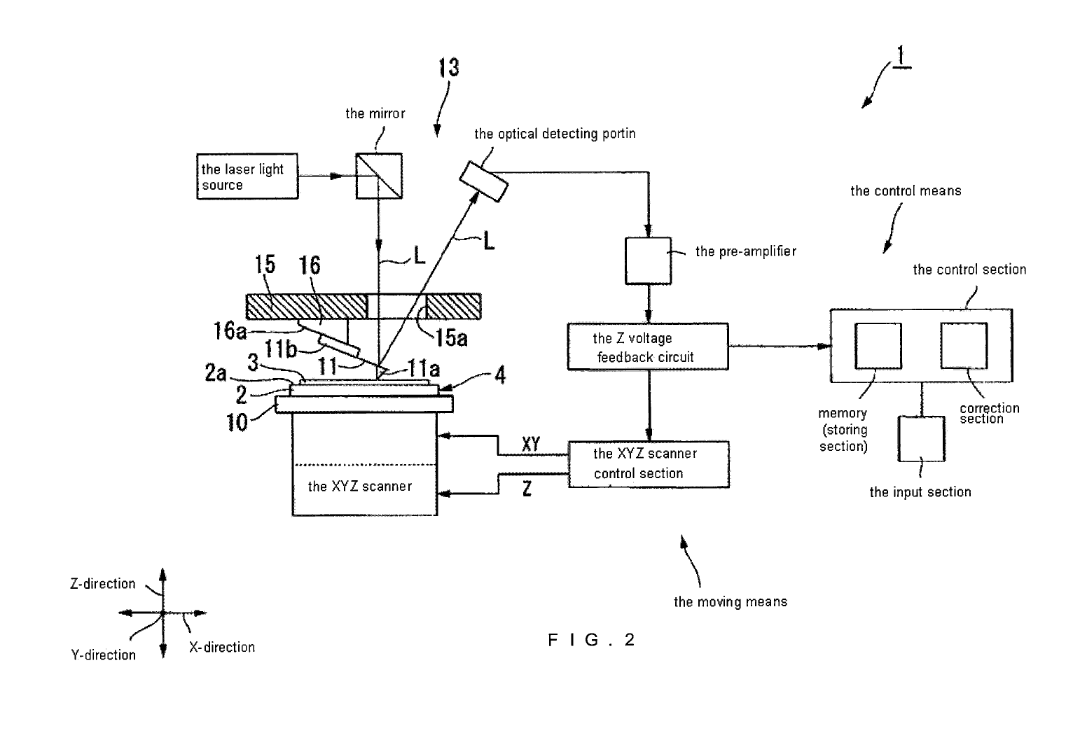

The photomask defect-shape recognition apparatus 1 of this embodiment, as illustrated in FIG. 2, includes a stage 10 for fixing the photomask 4, a probe 11 having at a tip thereof a probe tip 11a provided so as to oppose to the substrate 2, a moving means for relatively moving the substrate 2 and the probe tip 11a in an XY direction which is parallel to the substrate surface 2a and in a Z direction which is perpendicular to the substrate surface 2a, a displacement measuring means 13 for measuring a displacement of the probe 11 (bending), and a control means 14 for totally controlling the respective components.

The probe tip 11a is made of a hard material such as a diamond so that the defect portion 5 is easily cut away, and is formed so that a surface that abuts against the defect portion 5 at the cutting processing forms a right angle (perpendicular) to the defect portion 5. Further, the probe 11 is made of silicon or the like, and is supported in a cantilever state by a body portion 11b. The body portion 11b is detachably fixed using a wire or the like (not shown) to a mounting surface 16a of a slanted block 16 which is fixed to a holder portion 15. With this structure, the probe 11 is fixed while being inclined by a predetermined angle with respect to the substrate surface 2a.

The holder portion 15 is mounted to a frame (not shown) so as to be positioned upward of the substrate 2. Further, the holder portion 15 has an opening 15a formed therein, which allows a laser light L described later to enter into a reflecting surface (not shown) formed on a back surface the probe 11 and also allows the laser light L reflected on the reflecting surface to exit.

The stage 10 is mounted on the XYZ scanner 20, and the XYZ scanner 20 is mounted on a vibration-isolated table (not shown). The XYZ scanner 20 is, for example, a piezoelectric element, and is configured to minutely move in an XY direction and in a Z direction by being applied with a voltage from an XYZ scanner control section 21 including an XY scanning system and a z servo system. Specifically, the XYZ scanner 20 and the XYZ scanner control section 21 each function as the above-mentioned moving means 12.

Further, provided above the holder portion 15 are a laser light source 22 which emits the laser light L towards the reflecting surface formed on the back surface of the probe 11, and a optical detecting portion 24 which is influenced by the laser light L reflected on the reflecting surface using a mirror 23. Note that, the laser light L emitted from the laser light source 22 passes through the opening 15a of the holder portion 15 to reach to the reflecting surface, and after being reflected on the reflecting surface, the laser light L enters the optical detecting portion 24 by passing through the opening 15a again.

The optical detecting portion 24 is, for example, a photodiode having an incident surface which is divided into two or four, and detects the displacement (bending) of the probe 11 judging from an incident position of the laser light L. Then, the optical detecting portion 24 outputs the detected displacement of the probe 11 as a DIF signal to the pre-amplifier 25. Specifically, the laser light source 22, the mirror 23, and the optical detecting portion 24 each function as the displacement measuring means 13 for measuring the displacement of the probe 11.

Further, the DIF signal output from the optical detecting portion 24 is amplified by the pre-amplifier 25, and then transmitted to a Z voltage feedback circuit 26. The Z voltage feedback circuit 26 performs a feedback control of the XYZ scanner control section 21 so that the transmitted DIF signal becomes always constant. With this structure, when the substrate surface 2a is subjected to AFM observation, the distance (height) between the substrate 2 and the probe tip 11a may be controlled so that the displacement of the probe 11 becomes constant.

Further, the control section 27 is connected to the Z voltage feedback circuit 26, and the control section 27 is configured so as to obtain the observation data on the substrate surface 2a based on a signal for vertical movements from the Z voltage feedback circuit 26. With this structure, the mask pattern 3 formed on the substrate 2 and an image of the defect portion 5 of the mask pattern 3 may be obtained.

Specifically, the Z voltage feedback circuit 26 and the control section 27 each function as the control means 14. Note that, the control means 14 is set so as to perform AFM observation to recognize in detail the defect portion 5 being an object of the cutting processing, and thereafter subsequently, to perform the cutting processing of the defect portion 5.

Further, an input section 28 through which an operator may input various information is connected to the control section 27, thereby being capable of freely setting the observation area, etc. for conducting AFM observation through the input section 28. With this structure, the operator may set the observation area E based on a rough positional data of the defect portion 5 specified by the defect inspection apparatus. Then, the control section 27 is set so as to perform AFM observation and the cutting processing within the observation area E, if the observation area E is set.

Further, the control section 27 includes a memory (storing section) 27a for storing as a reference image an observation image in which an edge line of the defect portion 5 is first confirmed at the time of AFM observation and a correction section 27b for correcting the edge line of the defect portion 5 which is confirmed from the observation image obtained by the scanning performed hereinafter into a normal line while referring to the reference image. Then, it is configured to recognize the shape of the defect portion 5 based on the observation image after the correction. About this configuration, the description is made in detail hereinbelow.

Note that, in this embodiment, when conducting AFM observation and the cutting processing, as illustrated in FIG. 1, the control means 14 performs the control of the respective components such that, while scanning the probe tip 11a in a parallel direction (arrow C direction) with respect to a mask pattern 3a of the mask pattern 3, the scanning is performed repeatedly multiple times in a direction from a tip end side of the defect portion 5 towards the mask pattern 3 (arrow D direction).

Next, descriptions are made of a photomask defect-shape recognition method for recognizing the shape of the defect portion of the mask pattern 3 in detail by using thus constructed photomask defect-shape recognition apparatus 1 and a photomask correction method for correcting the defect portion 5, the shape of which is recognized by the photomask defect-shape recognition method, by the cutting processing.

The photomask defect-shape recognition method of the present invention is a method of recognizing the shape of the defect portion 5 by performing the storing step and the correcting step alternately. Besides, the photomask correction method is a method of subjecting, after completing the photomask defect-shape recognition method, the recognized defect portion 5 to the cutting processing to be removed. The respective steps are described in detail hereinbelow.

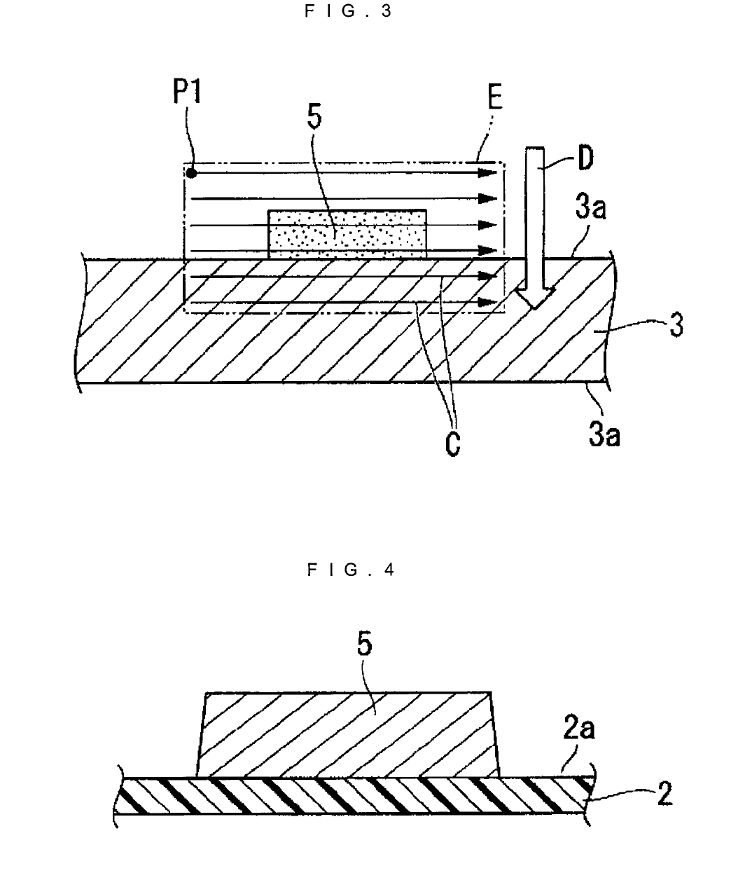

First, an initial setting is performed. Specifically, after fixing a photomask 4 on a stage 10, positions of a laser light source 22 and a optical detecting portion 24, a mounting state of a probe 11, and the like are adjusted so that a laser light L positively enters a reflecting surface of the probe 11, and further, the reflected laser light L positively enters the optical detecting portion 24. Subsequently, an operator specifies as an observation area E, as illustrated in FIG. 3, through an input section 28, a periphery of the defect portion 5 whose position is specified by the defect inspection apparatus.

After completing the initial setting, observation is started.

When the observation is started, the control means 14 causes the probe 11 to conduct scanning within the specified observation area E to obtain an observation image through AFM observation, and performs the recognition step for recognizing the shape of the defect portion 5 in detail.

Specifically describing, first, an XYZ scanner 20 is driven to move the probe tip 11a to a point P1 illustrated in FIG. 3. At the point P1, the probe tip 11a and the substrate 2 are allowed to approach each other, and the probe tip 11a and the substrate surface 2a are brought into contact with each other with a minute force. At this time, as the probe tip 11a approaches to the substrate surface 2a, the probe 11 gradually bends to be displaced. Thus, based on this displacement, detection may be made with high precision as to whether or not the probe tip 11a is brought into contact with the substrate surface 2a with a minute force.

Subsequently, the XYZ scanner 20 is driven to allow the probe tip 11a to scan in a parallel direction (arrow C direction) with respect to the edge 3a of the mask pattern 3, while controlling the height of the XYZ scanner 20 so that the displacement of the probe 11 becomes constant, and the scanning is performed repeatedly multiple times in a direction from a tip side of the defect portion 5 towards the mask pattern 3 (arrow D direction). At this time, depending on irregularities, the probe 11 tends to bend and displace. Accordingly, the position of the incident laser light L entering the optical detecting portion 24 differs. Then, the optical detecting portion 24 outputs a DIF signal in accordance with displacement of the incident position to a pre-amplifier 25. The output DIF signal is amplified by the pre-amplifier 25, and then transmitted to the Z voltage feedback circuit 26.

The Z voltage feedback circuit 26 minutely moves the XYZ scanner 20 in a Z direction by the XYZ scanner control section 21 so that the DIF signal transmitted becomes constant (that is, the displacement of the probe 11 becomes constant), to thereby conduct a feedback control. With this operation, the scanning may be carried out with a state in which the height of the XYZ scanner 20 is controlled so that the displacement of the probe 11 becomes constant. Further, the control section 27 may conduct the surface observation within the observation area E based on a signal for vertically moving the XYZ scanner 20 through the Z voltage feedback circuit 26. As a result, within the specified observation area E, the observation images of a part of the mask pattern 3 and the defect portion 5 may be recognized, thereby being capable of specifying the contour shape of the defect portion 5 in detail.

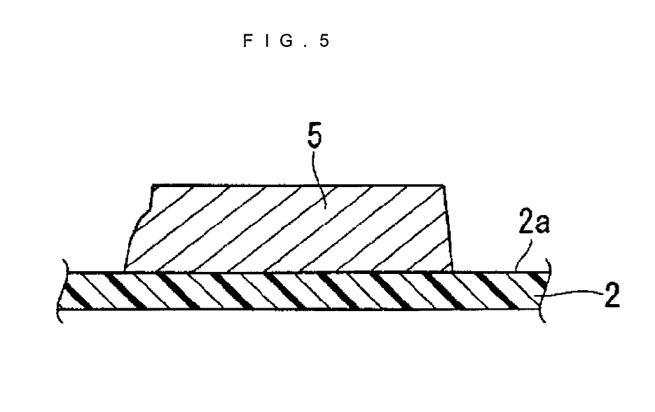

Describing this AFM observation in detail, first, AFM observation is started, and a storing step of storing as a reference image an observation image illustrated in FIG. 4, in which the edge line of the defect portion 5 is first confirmed, to a memory 27a is conducted. Specifically, the observation image obtained using a clean probe tip 11a to which no foreign matter is attached is stored as the reference image. Hereinafter, the scanning is repeated for AFM observation. However, there is a fear of a part of the defect portion 5, which is cut by the probe tip 11a during the cutting processing, being attached to the probe tip 11a. In this case, the obtained observation image becomes a double-tips image as illustrated in FIG. 5, the edge line of the defect portion 5 may not be clearly recognized. However, the observation image which is obtained when the probe tip 11a is still clean is stored, as illustrated in FIG. 4, the accurate edge line of the defect portion 5 may be obtained without the influence of the double-tips image.

Subsequently, the scanning is repeatedly performed to conduct the AFM observation within the observation area E. However, the observation image obtained by the scanning which is performed after the storing step may become the double-tips image as described above. For that reason, the correction section 27b performs the correcting step of correcting the edge line of the defect portion 5 which is confirmed from the observation image obtained by the scanning after the storing step into a normal line with reference to the reference image. By conducting this correction, it is possible to cancel the influence of the double-tips caused by the attachment of the foreign matter to the probe tip 11a, and to presume the correct edge line of the defect portion 5.

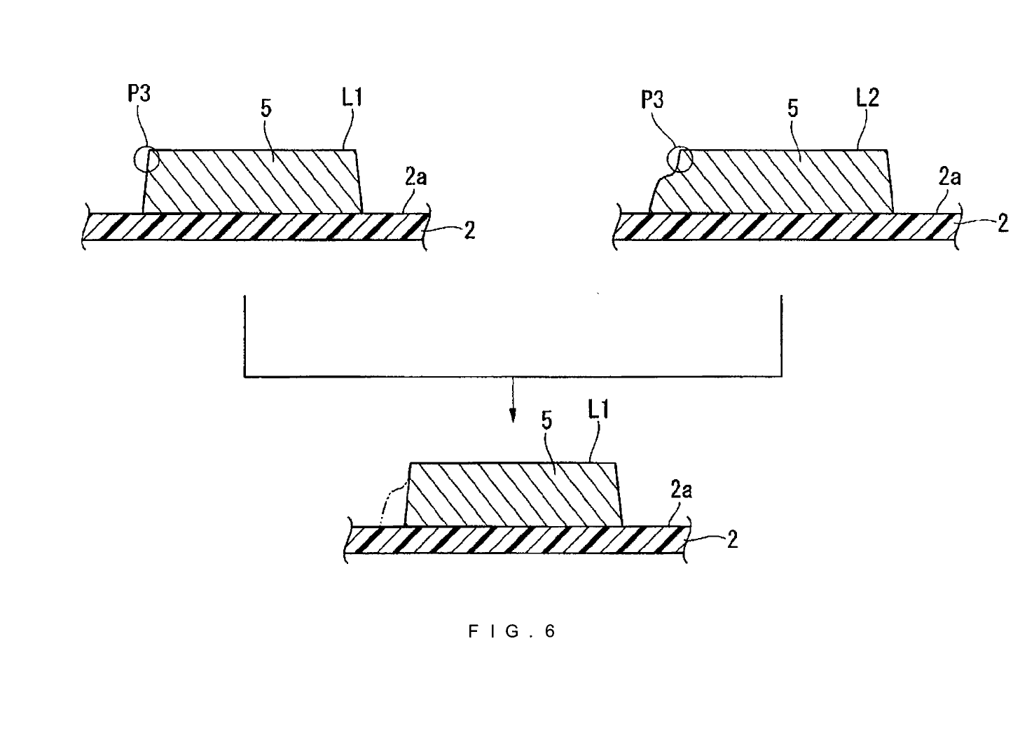

As an example of the correction, for example, the correction is performed by the method using the matching. Description is specifically made thereof with reference to FIG. 6. At the correcting step, the edge line L1 stored in the memory 27a and the edge line L2 obtained by the scanning performed after obtaining the reference image are subjected to matching to compare therebetween. Here, in the case of being influenced by the double-tips image due to attachment of the foreign matter to the probe tip 11a, both the edge lines L1 and L2 do not completely match with each other, and the difference is caused only the portion which is influenced by the double-tips image. Therefore, the line of the portion where the difference is caused is corrected so as to match with the edge line L1 stored in the memory 27a. With this operation, the correction of the portion, which is influenced by the double-tips, may be made, and hence the correct edge line L1 of the defect portion may be assumed.

Note that, when conducting the matching, both the edge lines L1 and L2 may be subjected to the matching using common geometrical feature as the reference. For example, as illustrated in FIG. 6, in the case where a part of the side surface of the defect portion 5 is influenced by the double-tips, the rest part of line (line P3 shown in FIG. 6) matches with the edge line L1 stored in the memory 27a, the matching may be may using this portion as a reference.

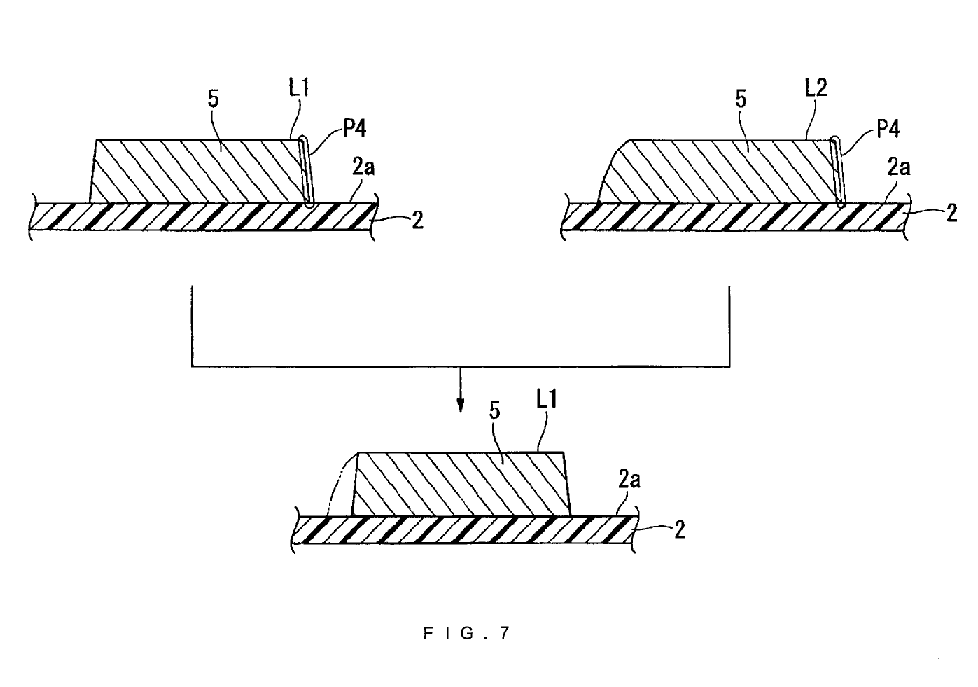

Further, as illustrated in FIG. 7, in the case where the entire side surface of the defect portion 5 is influenced by the double-tips, the line of the side surface on an opposite side (line P4 shown in FIG. 7) matches with the edge line L1 stored in the memory 27a, the matching may be performed using this portion as a reference. Like this, both the edge lines L1 and L2 may be subjected to matching using the common geometrical feature as a reference.

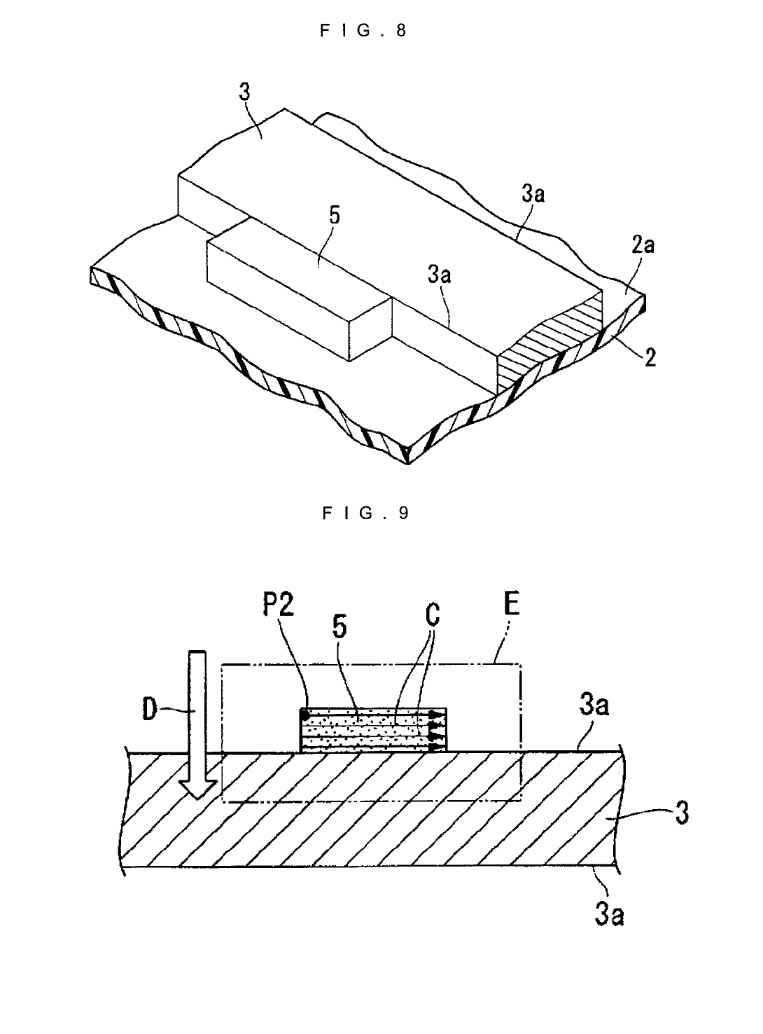

By correcting the edge line as describe above, as illustrated in FIG. 8, it is possible to accurately recognize the contour shape of the defect portion 5 without being influenced by the double-tips image while distinctly distinguishing the mask pattern 3 from the defect portion 5. Note that, the photomask defect-shape recognition method terminates at this time. In this embodiment, description is then transferred to a photomask correction method.

Specifically, after conducting the AFM observation described above, the control section 27 performs the scanning repeatedly multiple times while pressing the probe tip 11a with a predetermined force to the defect portion 5 whose shape is recognized in detail through AFM observation, and performs the cutting processing of cutting the defect portion 5 to be removed.

Specifically describing, first, an XYZ scanner 20 is driven to move the probe tip 11a to a point P2 shown in FIG. 9. At the point P2, the probe tip 11a and the substrate 2 are allowed to approach to each other, and the probe tip 11a and the defect portion 5 are brought into contact with each other with a predetermined force. At this time, as pressing the probe tip 11a, the probe 11 gradually bends to be displaced. Thus, based on this displacement, the probe tip 11a may be positively pressed with a predetermined force.

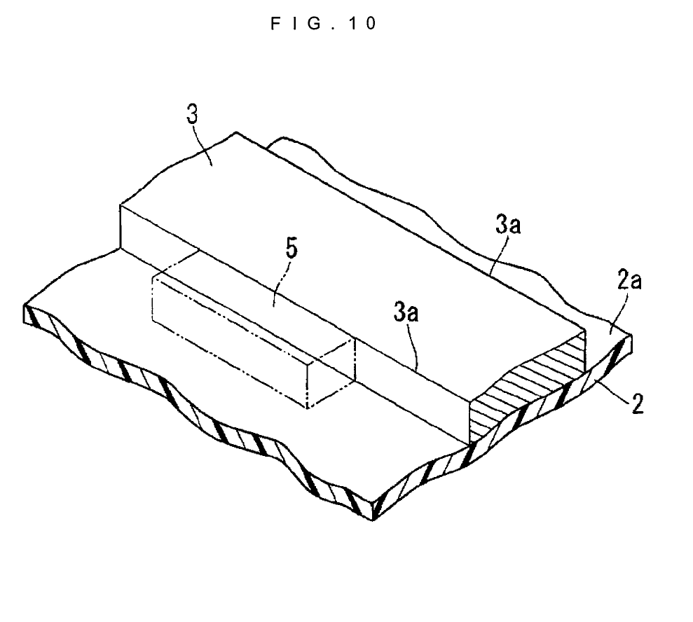

Subsequently, while controlling the pressing force, the XYZ scanner 20 is driven to scan the probe tip 11a in a direction parallel to the edges 3a of the mask pattern 3 (arrow C direction), and as illustrated in FIG. 9, the scanning is repeatedly performed in a direction from the tip of the defect portion 5 towards the mask pattern 3 side (arrow D direction). With this operation, the defect potion 5 may be cut gradually, and as illustrated in FIG. 10, finally, the entire defect portion 5 may be cut and removed. In particular, the cutting processing is performed from the tip of the defect portion 5, the processing may be performed with small cutting resistance, thereby being capable of efficiently conducting the cutting with a short period of time.

Further, different form the conventional apparatus and method which is influenced by the double-tips image, through AFM observation, the defect portion 5 and the mask pattern 3 is distinctly distinguished and the contour shape of the defect portion 5 is accurately recognized. Therefore, while preventing the troubles from occurring, such as cutting of the mask pattern 3 by mistake and the remainder of the defect portion 5 to be cut, as illustrated in FIG. 10, the defect portion 5 only may be removed by the cutting processing with high accuracy. As a result, the correction of the mask pattern may be made with high accuracy. Further, there may be obtained the photo mask 4 with high quality as an original plate for transfer of the image.

Moreover, in this embodiment, the probe tip 11a is scanned in a direction parallel to the edge 3a of the mask pattern 3 (arrow C direction). With this operation, the probe tip 11a may be scanned along the edge 3a of the mask pattern 3, and hence the image of the edge 3a may be obtained with high accuracy. Therefore, the mask pattern 3 may be easily corrected with high accuracy.

As described above, according to the photomask defect-shape recognition apparatus 1, the photomask defect-shape recognition method, and the photomask correction method in accordance with the embodiment of the present invention, AFM observation of the photomask 4 may be performed without being influenced by the double-tips image, and the contour shape of the defect portion 5 may be accurately recognized while distinctly distinguishing the defect portion 5 from the mask pattern 3. Accordingly, the degradation of processing accuracy associated with the fault recognition of the defect portion 5 may be prevented from occurring, thereby being capable of performing the cutting processing with high accuracy. Further, it is unnecessary for conducting the cleaning of the probe tip 11a as before, and hence there is no fear of causing the reduction of the throughputs associated with the cleaning and the degradation of processing accuracy due to drift.

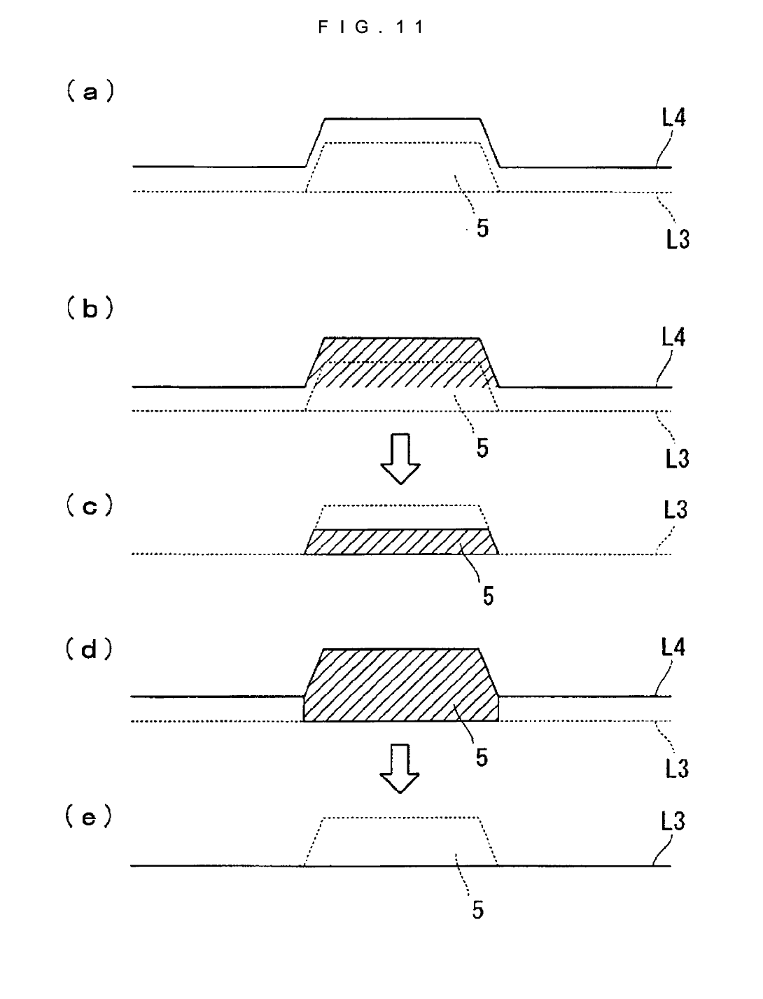

Hitherto, as illustrated in FIG. 11A, the correct edge line L3 of the mask pattern 3 and the defect portion 5 is erroneously recognized as the edge line L4 due to the influence of the double-tips image. For that reason, as illustrated in FIG. 11B, the position of the defect portion (area indicated by an oblique line in the figure) obtained from the observation image is recognized while being displaced from an actual position of the defect portion 5. For that reason, as illustrated in FIG. 11C, if the erroneously recognized defect portion is subjected to the cutting processing, there causes the cutting remainder in the actual defect portion 5 (area indicated by an oblique line in the figure).

On the contrary, according to the photomask defect-shape recognition apparatus 1 in accordance with the embodiment of the present invention, the correct edge line is presumed through matching, and hence, as illustrated in FIG. 11D, the actual defect portion 5 may be positively recognized from the observation image. Consequently, as illustrated in FIG. 11E, the defect portion 5 may be subjected to the cutting processing with high accuracy and without the cutting remainder.

Note that, a technical scope of the present invention is not limited to the above-mentioned embodiment, and various modifications may be made without departing from the purpose and the scope of the present invention.

For example, in the above-mentioned embodiment, the scanning method is employed in which the substrate 2 side is moved in a three-dimensional direction, but is not limited to the above-mentioned case, the probe 11 side may be moved in the three-dimensional direction. Further, there may employ a structure in which the prove 11 side is moved in a Z direction and the substrate 2 side is moved in an XY direction. Even in either case, only the scanning method differs, thereby being capable of taking the same operational effect as that of the above-mentioned embodiment.

Further, in the above-mentioned embodiment, it employs a structure in which, through the opening 15a formed in the holder portion 15, the laser light L is allowed to enter into the prove 11, and the reflected laser light L is allowed to outgo, but is not limited to this case. For example, the holder portion 15 may be made of a material which is optically transparent (for example, glass), and the opening 15a may be omitted.

Further, in the above-mentioned embodiment, the displacement measuring means 13 detects the displacement of the prove 11 using an optical lever method, it is not limited to the optical lever method, for example, there may employ a self detection method in which the prove 11 itself includes a displacement detection function (for example, piezoelectric resistance element).

Further, in the above-mentioned embodiment, when the edge line is corrected, a method using the matching is described by way of example, but is not limited thereto. For example, the correction may be conducted using as an index the inclined angle of the side surface portion of the defect portion 5

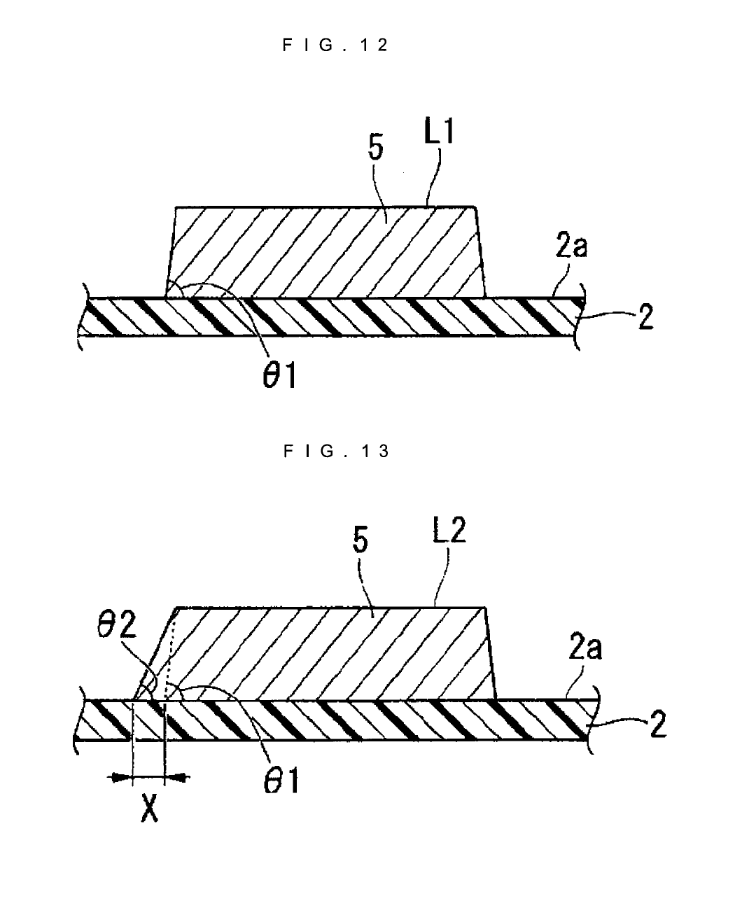

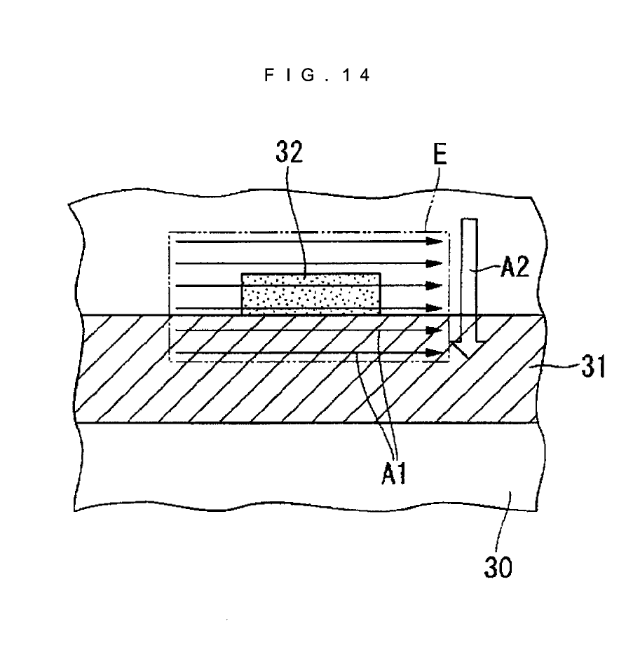

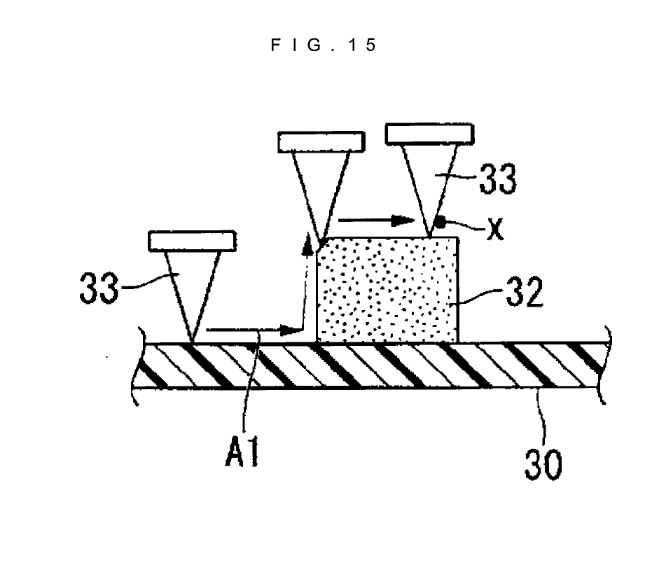

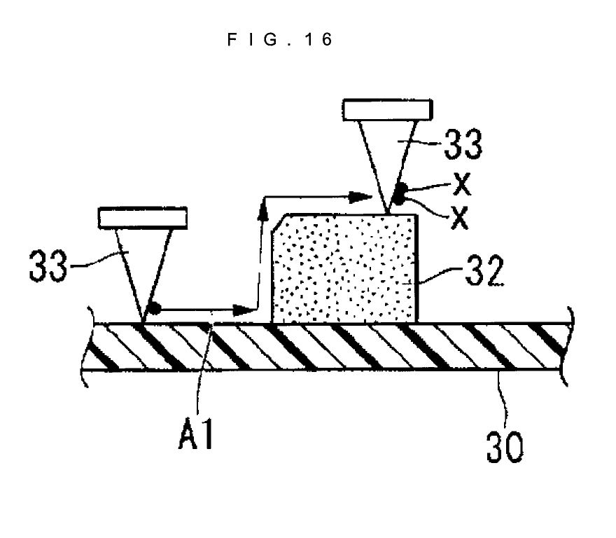

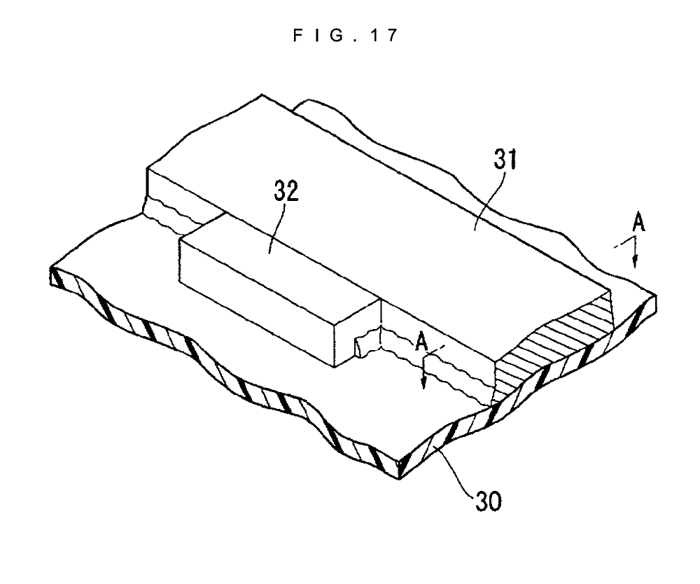

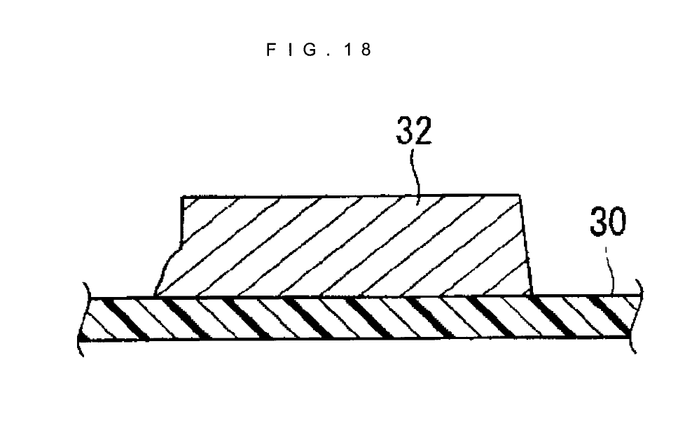

For the case described above, description is briefly made with reference to FIG. 12 and FIG. 13. First, as described in FIG. 12, from the edge line of the defect portion 5 L1 stored in the memory 27a, the inclined angle θ1 of the side surface of the defect portion 5 with respect to the substrate surface 2a is determined, and the determined angle θ1 is set as a reference angle. Typically, in the case where the foreign matter is attached to the probe tip 11a, the observation image is influenced by the foreign matter to cause a double-tips image, and the side surface portion is most influenced thereby. Specifically, in the observation image being the double-tips image, as illustrated in FIG. 13, influences such as a blur of the image and a double-overlapped image cause to confirm the edge line of the defect portion in which the side surface portion is inflated or deformed. Note that, the height of the defect portion 5 is not influenced by the double-tips even in the case of the probe tip 11a to which the foreign matter is attached.

For that reason, the inclined angle θ1 is determined in advance from the edge line which is not influenced by the double-tips image or the edge line L1 illustrated in FIG. 12 which is stored in the memory 27a, and the determined inclined angle θ1 is set as the reference angle.

Then, from the edge line L2 illustrated in FIG. 13 which is obtained by the scanning performed after obtaining the reference image, an inclined angle θ2 is determined as well. At this time, if the influence caused by the double-tips image is received, as described above, the side surface of the defect portion 5 is influenced markedly, resulting in change in the inclined angle θ2. Thus, from the inclined angle θ2 and the height, a displace amount X may be determined, and by correcting the changed inclined angle θ2 so as to match with the reference angle θ1, the portion which is influenced by the double-tips image may be corrected, and the correct edge line L1 of the defect potion 5 may be presumed.

What is claimed is:

1. A photomask defect-shape recognition apparatus for recognizing through AFM observation a shape of a projection type defect portion projected from a mask pattern of a photomask including a substrate and the mask pattern formed on the substrate with a predetermined pattern,
the photomask defect-shape recognition apparatus comprising:
a stage for fixing the photomask;
a probe having a probe tip provided on a tip of the probe, the probe tip being disposed opposingly to the substrate;
a moving means for relatively moving the substrate and the probe in a parallel direction of a surface of the substrate and in a vertical direction of the surface of the substrate;
a displacement measuring means for measuring displacement of the probe; and
a control means for repeatedly scanning multiple times, based on a result of measurement by the displacement measuring means, while controlling a distance between the probe tip and a surface of the substrate so that the displacement of the probe becomes constant, to thereby subject the defect portion to AFM observation, wherein
the control means comprises a storing section for storing as a reference image an observation image in which an edge line of the defect portion is first confirmed at a time of AFM observation; and a correction section for correcting the edge line of the defect portion confirmed through the observation image obtained by the scanning performed hereinafter into a normal line with reference to the reference image, and recognizes the shape of the defect portion based on the observed image after the correction.

2. A photomask defect-shape recognition apparatus according to claim 1, wherein the correction section compares the edge line stored in the storing section and the edge line obtained by the scanning performed after obtaining the reference image through matching to detect a difference therebetween, and corrects the line of a portion where the difference is detected, among the edge lines obtained by the scanning performed after obtaining the reference image, so as to match with the edge line stored in the storing section.

3. A photomask defect-shape recognition apparatus according to claim 1, wherein the correction section determines an inclined angle of a side surface of the defect portion with respect to a substrate surface from the edge line of the observation image stored in a storing section to set the inclined angle as a reference angle, and determines thereafter an inclined angle of the side surface of the defect portion with respect to the substrate surface from the edge line obtained by the scanning performed after obtaining the reference image, to thereby correct the inclined angle so as to match with the reference angle.

4. A photomask defect-shape recognition apparatus according to claim 1, wherein the control means scans multiple times the recognized defect portion while pressing the probe tip with a predetermined force to cut the defect portion to be removed.

5. A photomask defect-shape recognition method for recognizing through AFM observation a shape of a projection type defect portion projected from a mask pattern of a photomask including a substrate and the mask pattern formed on the substrate with a predetermined pattern by repeatedly scanning multiple times using a probe having a probe tip provided on a tip of the probe, while controlling a distance between the probe tip and a surface of the substrate so that a displacement of the probe becomes constant,
the photomask defect-shape recognition method comprising the steps of:
storing as a reference image an observation image in which an edge line of the defect portion is first confirmed at the time of AFM observation; and
correcting, after the storing step, the edge line of the defect portion confirmed through the observation image obtained by the scanning performed hereinafter into a normal line with reference to the reference image, wherein
the shape of the defect portion is recognized based on the observed image after the correction.

6. A photomask defect-shape recognition method according to claim 5, wherein, in the correction step, the edge line stored in the storing section and the edge line obtained by the scanning performed after obtaining the reference image is compared through matching to detect a difference therebetween, and the line of a portion where the difference is detected, among the edge lines obtained by the scanning performed after obtaining the reference image, is corrected so as to match with the edge line stored in the storing section.

7. A photomask defect-shape recognition method according to claim 5, wherein, in the correction step, an inclined angle of a side surface of the defect portion with respect to a substrate surface is determined from the edge line of the observation image stored in a storing section to set the inclined angle as a reference angle, and thereafter an inclined angle of the side surface of the defect portion with respect to the substrate surface is determined from the edge line obtained by the scanning performed after obtaining the reference image, to thereby correct the inclined angle so as to match with the reference angle.

8. A photomask defect correction method, comprising, after recognition of a shape of a photomask defect portion by the photomask defect-shape recognition method according to claim 5, a processing step of repeatedly scanning multiple times while pressing a probe tip to the recognized defect portion with a predetermined force to cut and remove.
